(19) United States
(12) Patent Application Publication
(10) Pub. No.: US 2015/0083195 A1
(43) Pub. Date: Mar. 26, 2015

(54) TRANSPARENT SOLAR ENERGY COLLECTOR

(71) Applicant: SUNPARTNER, Aix En Provence (FR)

(72) Inventor: Jöel Gilbert, Eguilles (FR)

(73) Assignee: SUNPARTNER, Aix En Provence (FR)

(21) Appl. No.: 14/386,913

(22) PCT Filed: Mar. 19, 2013
(86) PCT No.: PCT/FR2013/000075

§ 371 Date: Sep. 22, 2014

(30) Foreign Application Priority Data
Mar. 22, 2012 (FR) 12 00859

(51) Int. Cl. F24J 2/04; H01L 31/052; F24J 2/05

(52) U.S. Cl. CPC F24J 2/0494; F24J 2/05; H01L 31/0525
USPC 136/248; 126/650

(57) ABSTRACT

The invention concerns a device for collecting infrared solar radiation by heating a circulating blade of air circulating between two transparent glazed walls. The first glazed wall polarises light in a circular manner. The second glazed wall reflects infrared radiation towards the first glazed wall. The infrared radiation which has been reflected has changed polarisation direction and is then absorbed by the first glazed wall which heats up, and in turn heats the circulating blade of air in contact with same.

The present invention relates to solar energy collectors and more particularly to thermal solar collectors.

### PRIOR ART

Solar energy collectors convert solar light into heat energy, electrical energy, or chemical energy, or a combination of these various energies. For this, solar collectors use materials that absorb and convert all or some of the solar radiation received. This absorption depends on the absorbent material used and on the wavelength of the solar radiation. Ideally a black body can absorb the majority of the solar radiation and convert it into heat, which raises the temperature of the collector.

The thermal solar panels that use this principle are usually opaque since they absorb the wavelengths that are in the visible range, and also the wavelengths which are in the ultraviolet and infrared range.

However, it may be advantageous in certain applications to use solar collectors that are transparent to visible light and that only collect the ultraviolet and/or infrared radiation of the solar spectrum. This is the case in particular in the field of construction and agriculture where energy is needed to regulate the temperature of rooms or greenhouses while natural light is also needed inside these spaces.

For simplicity of language, the term “transparent” will be used subsequently to indicate that the transparent element lets visible light through, independently of its behavior in other wavelength ranges.

There are already transparent glass panes that have the property of reflecting infrared radiation, but this radiation is not collected for heating purposes, or else it is collected but with quite a low efficiency.

Glass panes also exist that are referred to as “parietodynamic” which consist of transparent triple glazing inside which a stream of air flows which is heated by the greenhouse effect, that is to say that the glass retains a portion of the infrared radiation that it receives while forming a thermal insulation barrier toward the outside. The air heated between the various glazed walls is forced into the adjoining room in order to heat it while enabling the external light to pass through the glass panes. As ordinary transparent glass panes only absorb a little infrared radiation, the efficiency of this device is reduced.

### OBJECTIVE OF THE INVENTION

The main objective of the invention is to improve the efficiency of transparent thermal solar collectors owing to an optical device that will increase the degree of collection of invisible solar energy, mainly that of infrared radiation, while retaining, for said collector, a good transparency to visible light.

Another objective of the invention is to propose a device for collecting solar energy that is transparent or semi-transparent and of which the degree of transparency and the degree of collection of the infrared radiation can be easily adjusted by an appropriate choice of the materials used.

Another objective of the invention is to propose a device for collecting solar energy that is simple and economic, and that can easily be integrated into all sorts of support structures in order to make the solar collector able to be used in a variety of application contexts, whether it is in particular for construction, transport means or other contexts.

### SUMMARY OF THE INVENTION

The device according to the invention consists of one or more transparent glazed walls, also referred to simply as glass panes, which are either separated by a circulating air space, or adhesively bonded to one another and are adjacent to an air space with which they can carry out a transfer of heat energy.

Each glass pane or glazed wall comprises two faces, namely one face referred to as the outer face and one face referred to as the inner face, knowing that the outer face will be defined as being that exposed to the incident light, especially solar light, and the inner face is that facing in the opposite direction.

The first glazed wall is that which receives the external solar light. According to the invention, this first glazed wall has undergone an optical treatment, at the surface or in its bulk, so as to polarize, for example circularly, the light that passes through it. This circular polarization may be carried out in a direction which by convention is either “levorotatory” for a left-hand polarization plane, or “dextrorotatory” for a right-hand polarization plane. The rotatory power of this first glazed wall is due to an asymmetric microscopic structure included on its surface or in its bulk, such as for example an arrangement of atoms that form an asymmetric spatial geometrical figure of molecules or crystals so that said geometrical figure cannot be superimposed with its mirror image. These two asymmetric microscopic structures, which are images of one another but which are not superimposable, have the known property of rotating, in opposite directions, the electrical field of the light waves. This rotating property is defined by the terms “optical activity” and/or “circular birefringence”. It is obtained using certain organic compounds such as sugars (saccharose, fructose, dextrose).

Techniques which make it possible to give this circular birefringence property to a glass pane or to a film are already known to a person skilled in the art and will not be described in detail. Mention will be simply be made of one of these techniques, the one for example that consists in superimposing two optically active surfaces, the first surface having the property of polarizing the light in a linear manner, and the other surface having the property of slowing the electrical component of the light wave by a quarter wave.

According to the invention, reflecting means are arranged behind the polarizing means in the optical path of the incident light. These reflecting means are, for example, arranged on a second glazed wall which has itself also undergone an optical treatment, at the surface or in its bulk, so as to reflect the incident infrared radiation while letting through a greater or lesser portion of the visible light.

As is known, the polarized infrared radiation that is reflected by the second glass pane will see its polarization plane change during reflection thereof. Specifically, it is a property of wave optics that an electromagnetic wave for which the polarization plane is dextrorotatory becomes levorotatory, and vice versa, when it is reflected by a reflecting surface, especially a glass surface or a metallic surface. The polarized infrared radiation reflected by the second glass pane and which therefore has, for example, a levorotatory polarization plane, goes toward the first glass pane with dextrorotatory polarization, which will then stop and absorb this infrared radiation since it is of reverse polarization.

However, the absorption of the infrared rays by the polarizing filter of the exposed glass pane will raise its temperature and give up its heat by conduction and by convection to its surroundings, and especially to the air adjoining the glass pane containing the polarizing means. The air thus heated will then be able to be channeled in order to circulate to rooms to be heated or to be cooled, the cooling being able to be carried out for example owing to well-known processes for converting heat energy. The hot air, or the cold air thus produced, can then optionally be stored in a space provided for this purpose.

The result is that the solar energy collector according to the invention may remain very transparent for the visible light that passes through it normally, but it has become opaque for a large portion of the infrared radiation that has been absorbed by the polarizing filter. The infrared rays have therefore been converted to heat energy, which has enabled the rise in temperature of the polarizing filter, of the glass pane that bears it, and of the air space which is in contact therewith.

The principle of the invention can easily be adapted to several configurations of glazed walls, for example a configuration in which polarizing means and reflecting means are integrated into a single glazed wall, or a configuration in which the polarizing means are integrated into a first glazed wall and the reflecting means are integrated into a second glazed wall.

In the case of a single glazed wall, this wall is surrounded by air spaces or spaces filled with another fluid that make it possible to recover the heat formed in the glass pane due to the absorption of the infrared radiation, and these air spaces may be delimited by transparent glass panes simply serving as insulating double glazing.

Similarly, when two different glazed walls are used, they may be separated by an air space or a space filled with another heat transfer medium that is positioned between them, and they may optionally be provided, toward the outside, with an insulating and transparent double glazing.

According to another embodiment of the invention, the two glass panes that are optically treated in order to obtain polarizing means and reflecting means are not separated by an air space, but are directly bonded to one another so as to ensure a thermal contact between them, which will not change the successive optical effects of reflection then absorption of the polarized infrared radiation, and of heating of the absorbent glass pane which results therefrom. In this scenario, one or more air spaces in contact with the hot glass pane may be reconstructed on either side of the two bonded glass panes, by simple delimitation with a third and a fourth transparent glass pane acting simply as double glazing around the structure of the two bonded polarizing and reflecting glass panes.

The transparent solar collector according to the invention may also be provided on one part of its surface with means for concentrating the incident solar light, and/or means for concentrating the visible light passing through the collector.

The transparent solar collector according to the invention may also be provided on one part of its surface with transparent or non-transparent photovoltaic cells that make it possible to generate electrical energy from a portion of the incident solar radiation, whilst the infrared radiation is used to heat a glazed wall of the collector, in accordance with the principle of the invention. This makes it possible to generate heat and electricity from one and the same solar, yet least partially transparent, collector.

In a detailed manner and in order to implement the principles described above, one subject of the invention is a device for collecting solar energy comprising at least one transparent or semi-transparent glazed wall having one face exposed to the incident light from the sun, characterized in that it comprises, in the path of the incident rays, light-polarizing means, followed by reflecting means suitable for reflecting toward said exposed face all or some of the polarized light and in imparting thereto a modified polarization so that the reflected light is absorbed by said polarizing means and gives rise to heating of said glazed wall.

According to one particular embodiment of the invention, said polarizing means are chosen in order to polarize the incident light in a circular (levorotatory or dextrorotatory), elliptical or rectilinear manner and/or possess a circular birefringence property, and the reflecting means are chosen to reverse the polarization of the polarized light transmitted by the polarizing means.

The reflecting means may be chosen so as to reflect only one portion of the spectrum of light wavelengths received.

As a variant, the reflecting means may be chosen to reflect only all or some of the infrared component of the polarized light received and let through all or some of the visible component of the polarized light received.

In one particular embodiment, the polarizing means for polarizing the incident light consist of a polarizing filter positioned on the exposed face of the glazed wall, or integrated into the bulk of the glazed wall.

According to the invention, the means for reflecting the polarized light consist of a reflecting filter affixed to the rear face of the glazed wall, or integrated into the bulk of the glazed wall.

According to a first embodiment, said polarizing means and said reflecting means are integrated into a single glass pane intended to be heated under the effect of the absorption of the infrared radiation received from the reflecting means and that transmits the heat absorbed to at least one air space delimited by at least one transparent glass pane.

According to another embodiment, said polarizing means are integrated into a first glass pane, and said reflecting means are integrated into a second glass pane placed behind said first glass pane in the path of the incident light rays, said first glass pane being caused to heat up under the effect of the absorption of the infrared radiation received from the reflecting means. In this embodiment, the first glass pane and the second glass pane may be separated, for example, by an air space made to heat up in contact with said first glass pane. Alternatively, the first glass pane and the second glass pane may be fastened together and in thermal contact with one another so as to heat up together under the effect of the absorption of the infrared radiation by said first glass pane. The heat thus produced is then transmitted to at least one air space delimited on one side by the first and/or the second glass pane and on the other side by at least one transparent glass pane serving as insulating double glazing.

In the various embodiments envisaged, the sole glass pane or the first glass pane and/or the second glass pane is made of organic glass or made of crystalline glass.

According to the invention, the polarizing means and the reflecting means are produced by a surface treatment or a bulk treatment of the glazed walls. In particular, the reflecting means may advantageously be formed from metallic particles taken from aluminum, copper, nickel, cobalt, titanium, silver, gold and platinum.

In particular for the purposes of protecting people, the sole glass pane or the first and/or the second glazed wall reflects or absorbs ultraviolet radiation.

The appearance of the single glass pane or of the first and/or second glazed wall may vary, it being possible for these glass panes to be semi-transparent and/or colored.

According to one embodiment variant that is easy to implement, including on already-existing glazings, the polarizing means and/or the reflecting means are integrated into flexible and optionally self-adhesive films, that may be added and fixed to existing glazings in order to convert the latter into transparent solar collectors in accordance with the invention.

In order to perfect the heat transfers or to adapt them to the application requirements, the air space adjoining the glazed walls may be replaced by another gaseous, solid or liquid transparent fluid, or by a phase change material, or by a vacuum.

Advantageously, the device according to the invention additionally comprises an optic of concave mirror, lens, prism, Fresnel lens or heliostat type, for concentrating the incident solar light toward the face of the device exposed to the incident solar light, and/or in order to concentrate the light transmitted by the device.

In addition, in order to combine the conversion of solar energy into heat, with a generation of electric current, one variant of the device according to the invention comprises photovoltaic cells positioned over a portion of the surface of the glazed walls and/or of the transparent glass panes. Thus, a portion of the incident solar radiation or of the transmitted radiation shines on said cells and is converted into electricity, while another portion of the incident solar radiation is converted into heat.

In one particular embodiment, the photovoltaic cells which produce electricity also have the property of polarizing the light in a rectilinear manner. These photovoltaic cells are then positioned in micro-sized parallel strips spaced out by transparent strips, the width of which is less than 1 micron. A quarter wave film placed behind the photovoltaic polarizer will then give rise to the conversion of the linearly polarized light into a circularly polarized light while producing electricity.

The device according to the invention is preferably equipped with a mechanical system for ensuring the circulation of the gaseous or liquid fluids between and/or around the glazed walls, which makes it possible to transport the heat generated to rooms or other places where it is capable of being used.

Another subject of the invention is a device for collecting solar energy as defined above, additionally comprising a solid or flexible frame or support made of metal, wood or composite materials that is capable of adapting the collecting device to windows, sliding bay windows, greenhouse walls, swimming pool covers, garden sheds, aircraft windows, skylights, transport vehicle windows, billboards, shop windows, tiles, roofs, and to all devices that use transparent materials in the fields of construction, transport vehicles, bill posting and broadcasting of images, including electronic display screens.

### DETAILED DESCRIPTION OF THE INVENTION

The invention is now described in greater detail with the aid of the description of the figures.

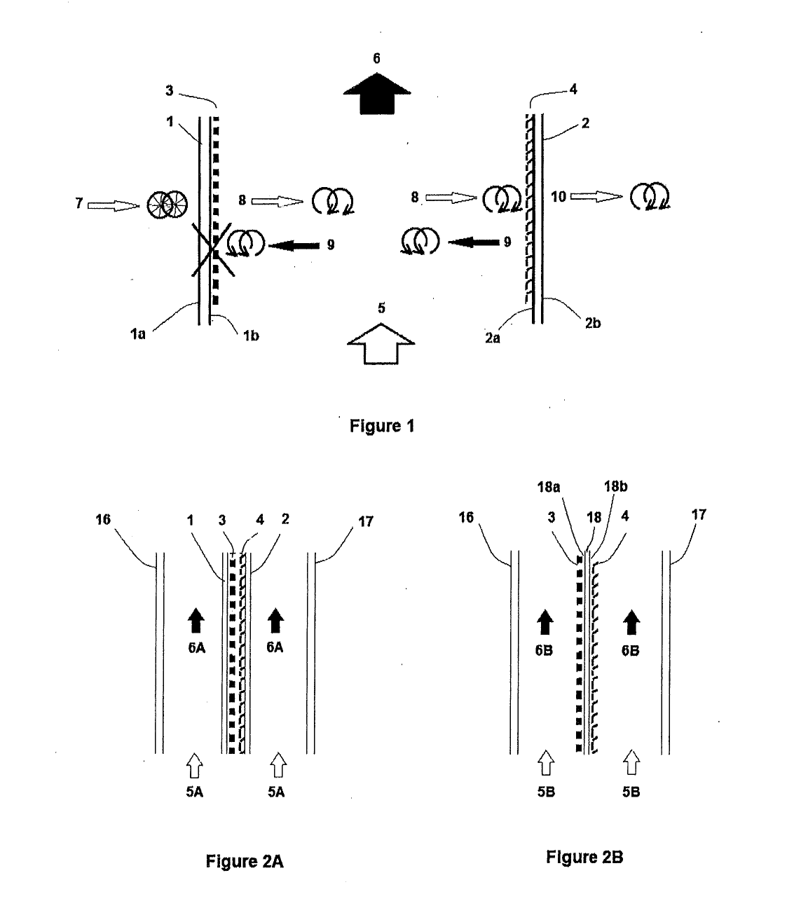

FIG. 1 is an elevation in cross section of one embodiment of the solar energy collector according to the invention, showing the principle of the structure using two glazed walls, and the optical functioning thereof.

FIG. 2A is a schematic diagram of one embodiment variant in which the two glazed walls are bonded together and surrounded by insulating double glazing.

FIG. 2B is a schematic diagram of one embodiment variant in which the two glazed walls are replaced by a single glass pane.

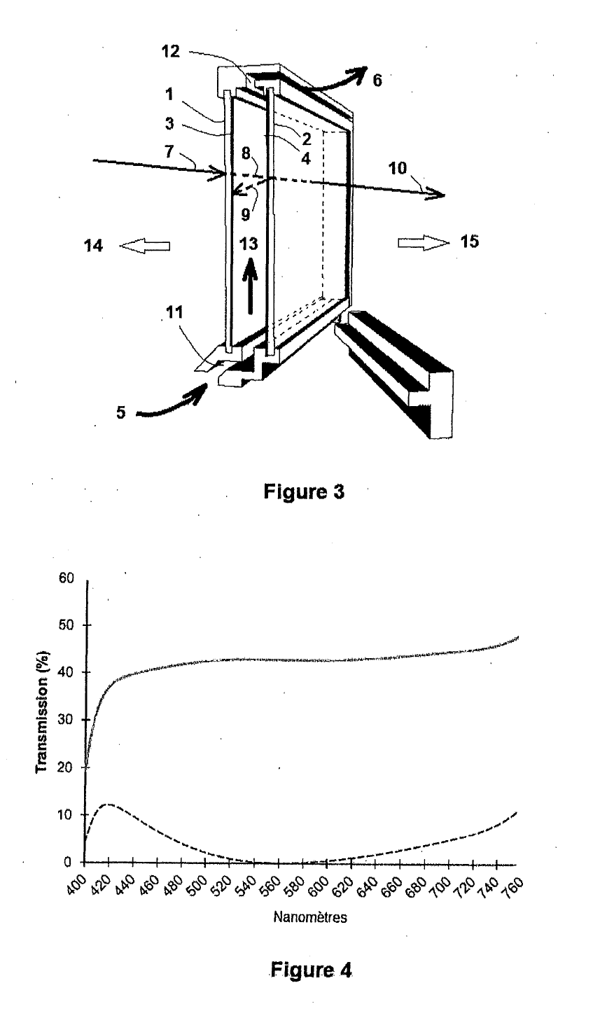

FIG. 3 is a perspective view of an exemplary embodiment of a house window which includes a solar energy collector according to FIG. 1.

FIG. 4 is a graph representing the light reflection and transmission rates of a circular polarizing filter that can be used as polarization means within the context of the device according to the invention.

The device according to FIG. 1 mainly consists of two transparent glass panes or glazed walls (1, 2) separated by or adjoining a circulating air space (5, 6). The first glazed wall (1) receives on its outer face (1a), or exposed face, the incident solar light (7).

This first glazed wall (1) has previously undergone an optical treatment (3), on the surface or in its bulk, in order to produce polarizing means that have the effect of polarizing, for example circularly, the incident light (7) which passes through it (8). This circular polarization may take place in a direction which, by convention, is either “levorotatory” for a left hand polarization plane, or “dextrorotatory” for a right hand polarization plane.

The second glazed wall (2) has itself also undergone an optical treatment (4), on the surface or in its bulk, in order to produce reflecting means that have the effect of reflecting the polarized light radiation (8), or a portion of this radiation, for example its infrared component, toward the first glazed wall, while allowing another portion of the light radiation, for example most of the visible light (10) to pass through the glass pane (2). Therefore, the device may remain transparent to visible light, but absorbs the infrared component of the light.

Specifically, the polarized infrared radiation that is reflected (9) by the second glass pane (2) has changed its polarization plane during its reflection. Thus, the polarization plane, for example dextrorotatory polarization plane, of the polarized light (8) becomes levorotatory in the reflected infrared radiation (9). The infrared radiation (9) that now has a levorotatory polarization plane goes toward the first glass pane (1) with dextrorotatory polarization plane, which will then stop and absorb this reflected infrared radiation (9) since it is of reverse polarization. The absorption of the reflected infrared rays (9) by the polarizing filter (3) of the first glass pane (1) will therefore raise the temperature of the polarizing filter and of the glass pane (1) that supports it. This glass pane (1) will then give its heat to the cold air (5) contained between the two glass panes (1, 2). The cold air (5) therefore heats up, and the air (6) thus heated which has circulated between the two glass panes (1, 2) is then sent toward the faces to be heated, either by convection, or preferably by forced circulation means.

FIG. 2A illustrates another embodiment of the invention, in which the two glazed walls (1, 2) optically activated by the polarizing and reflecting treatments (3, 4) are bonded to one another so as to be in thermal contact. In addition they are insulated from the outside by two transparent glass panes (16, 17) positioned on either side of the two bonded glass panes (1, 2) and that serve as insulating glazing. The spaces located between the two transparent glass panes (16, 17) and the two glazed walls (1, 2) are travelled through by an air space (5) that heats up (6) in contact with the semi-transparent solar collector that is the subject of the invention.

FIG. 2B illustrates an even simpler embodiment, in which the two glazed walls (1, 2) are replaced by a single glass pane (18) that integrates both the polarizing means (3) and the reflecting means (4), for example in the form of a polarizing filter (3) placed on the glass pane on the side of the incident solar light, and of a mirror (4) placed behind the polarizing filter in the optical path of the incident light. As in the variant from FIG. 2A, the single glass pane (18) provided with its polarizing means (3) and reflecting means (4) is thermally insulated from the surroundings by air spaces (5B, 6B) that are delimited and channeled by transparent insulating glazing (16, 17).

FIG. 3 is a concrete exemplary embodiment of the variant of the device according to FIG. 1, applied to the production of windows for houses. The window is composed of a double glazing (1, 2) held by a frame made of wood or made of another insulating material that contains openings (11, 12) which allow the circulation of external air (5) toward internal air (6) of the house with a circulation of the air (13) between the two glazed walls (1, 2). The outside opening (11) is preferably in a low position whereas the inside opening (12) is preferably in a high position (12) so as to create natural air circulation from outside (14) to inside (15) of the house. The first glazed wall (1) is made of 4 mm thick clear glass and is covered on its inner face with a 100 micron thick semi-transparent film (3) which circularly polarizes the incoming light (7) in a dextrorotatory direction, for example. The second glazed wall (2) is made from a 4 mm thick clear glass and is covered on its inner face with a semi-transparent film (4) that has the property of reflecting the infrared solar radiation, namely the radiation for which the wavelengths are between 0.76 and 2.5 microns. The properties of this film (4), without these values being restrictive as regards the scope of the characteristics of the device, are the following:
UV rejection: 99%
Reflection of visible light (mirror effects): 7%
Transmission of visible light: 70%
Total solar energy rejected (heat): 49%
Solar reflectance ratio: 27%
Solar absorptance ratio: 26%
Solar transmittance ratio: 47%
Glare reduction: 20%
Infrared (760 to 2500 mm) rejection: ˜70%
Thickness: 50 microns

The distance between the two glazed walls (1, 2) is 28 mm. The other dimensions of the window are, in this example:
Height: 1.90 m
Width: 0.85 m
Total thickness of the double glazing: 36 mm

Represented in FIG. 4 is the degree of transmission of a circular polarization filter that is merely used for the implementation of the polarizing means of the device according to the invention.

The upper curve represents, as a function of the wavelength, the degree of transmission of the incident light (7), after passing through the polarizing filter.

The lower curve represents the degree of transmission to the outside of the polarized radiation (9) after reflection by the reflecting means.

As can be seen on the lower curve, the degree of transmission to the outside is between 0 and 10% as a function of the wavelengths in the visible range. Of course, the use of a polarizing filter having degrees of transmission that are also very low or even close to zero in the infrared range will make it possible to trap the infrared radiation inside the device even better, which makes it possible to heat the glazed wall (1; 18) of the device as described above.

The optical functioning of the device according to FIG. 3 is then the following. The incident external light (7) becomes polarized (8) on passing through the first glass pane (1) and its polarizing film (3). An amount of 70% of the infrared radiation of this polarized light (8) is reflected (9) by the film (4) of the second glass pane (2) while reversing its direction of polarity which therefore becomes levorotatory. Furthermore, an amount of 70% of the visible light (10) passes through the second glass pane (2) and enters into the house. The radiation reflected by the infrared film (4) represents 49% of the solar energy received, i.e. if the losses due to the reflection to the outside (14) of the incident radiation (7) are taken into account, it is around 40% of the energy received as a whole by the window that is reflected by the infrared film (4) toward the air space (5) between the two glass panes (1, 2), which represents the equivalent of a power of 400 W/m² when the window is exposed to full sun. This energy is then absorbed by the polarizing filter (3) of the first glass pane (1) which is opaque for levorotatory polarized radiation (9) as is the case for radiation that results from the reflection on the infrared film (4). Under the effect of this absorption, the polarizing film (3) then heats up until temperatures greater than 60° C. are reached and gives up its heat to the air (13) with which it is in contact and which circulates between the two walls (1, 2). The hot air (6) is in this example injected directly into the room (15) adjacent to the window via the high opening (12) thereof.

In one different embodiment (not represented), the hot air (6) is recovered by an adsorption air conditioner in order to cool the room (15).

In total, the device according to the invention makes it possible to collect close to 40% of the solar energy while allowing 70% of the visible light to pass through. By comparison, conventional devices of parietodynamic type that only use double glazing (1, 2) or triple glazing and optionally an infrared film (4) of the same quality but without the polarizing filter (3) which characterizes this invention, collect only 10% of the solar radiation.

The device according to the invention is particularly suitable for collecting solar energy owing to glazed walls that are mainly transparent to visible light.

### ADVANTAGES OF THE INVENTION

Ultimately, the invention makes it possible to collect much more solar energy than conventional double or triple glazing while retaining a good transparency to visible light.

1. A device for collecting solar energy comprising:
at least one transparent or semi-transparent glazed wall having one face exposed to incident radiation from the sun, and, in the path of the incident radiation, light-polarizing means, and
reflecting means downstream of the light-polarizing means for reflecting toward said exposed face at least some of the polarized light and imparting thereto a modified polarization so that the reflected light is absorbed by said polarizing means and causes heating of said glazed wall.

2. The device as claimed in claim 1, wherein said polarizing means polarize the incident light in a circular (levorotatory or dextrorotatory), elliptical or rectilinear manner and/or possess a circular birefringence property, and wherein the reflecting means reverse the polarization of the polarized light transmitted by the polarizing means.

3. The device as claimed in claim 1, wherein the reflecting means reflect only one portion of the spectrum of light wavelengths received.

4. The device as claimed in claim 3, wherein said reflecting means reflect only all or some of the infrared component of the polarized light received and let through all or some of the visible component of the polarized light received.

5. The device as claimed in claim 1, wherein the polarizing means for polarizing the incident light comprises a polarizing filter positioned on the exposed face of the glazed wall, or integrated into the bulk of the glazed wall.

6. The device as claimed in claim 1, wherein the means for reflecting the polarized light comprises a reflecting filter affixed to the rear face of the glazed wall, or integrated into the bulk of the glazed wall.

7. The device as claimed in claim 1, wherein said polarizing means and said reflecting means are integrated into a single glass pane that is heated under the effect of the absorption of the infrared radiation received from the reflecting means and that transmits the heat absorbed to at least one space delimited by at least one transparent glass pane.

8. The device as claimed in claim 1, wherein said polarizing means are integrated into a first glass pane, and said reflecting means are integrated into a second glass pane placed behind said first glass pane in the path of the incident light rays, said first glass pane being caused to heat up under the effect of the absorption of the infrared radiation received from the reflecting means.

9. The device as claimed in claim 8, wherein said first glass pane and said second glass pane are separated by an air space caused to heat up in contact with said first glass pane.

10. The device as claimed in claim 8, wherein said first glass pane and said second glass pane are fastened together and in thermal contact with one another so as to heat up together under the effect of the absorption of the infrared radiation by said first glass pane, and wherein the heat thus produced is transmitted to at least one air space delimited on one side by the first and/or the second glass pane and on the other side by at least one transparent glass pane.

11. The device as claimed in the sole glass pane (18) or the first glass pane (1) and/or the second claim 7, wherein at least one of the glass panes is made of organic glass or made of crystalline glass.

12. The device as claimed in claim 1, wherein said polarizing means and said reflecting means are produced by a surface treatment or a bulk treatment of the glazed wall.

13. The device as claimed in claim 1, wherein the reflecting means are formed from metallic particles selected from the group consisting of aluminum, copper, nickel, cobalt, titanium, silver, gold and platinum.

14. The device as claimed in claim 7, wherein at least one of the glass panes reflects or absorbs ultraviolet radiation.

15. The device as claimed in claim 7, wherein at least one of the glass panes is semi-transparent and/or colored.

16. The device as claimed in claim 1, wherein said polarizing means and/or said reflecting means are integrated into flexible films.

17. The device as claimed in claim 7, wherein the space adjoining the glass panes contains a gaseous, liquid or solid transparent fluid, or a phase change material or a vacuum.

18. The device as claimed in claim 1, further comprising an optic of concave mirror, lens, prism, Fresnel lens or heliostat type, for concentrating the incident solar light toward the exposed face of the device, or in order to concentrate light transmitted by the device.

19. The device as claimed in claim 1, further comprising photovoltaic cells positioned over a portion of the surface of the glazed wall and/or of transparent glass panes spaced from the glazed wall so that a portion of the incident solar radiation or of transmitted radiation shines on said cells and is converted into electricity, while another portion of the incident solar radiation is converted into heat.

20. The device as claimed in claim 19, wherein said photovoltaic cells are positioned in parallel strips spaced out by transparent strips, the width of which is less than 1 micron, so that said photovoltaic cells carry out both the role of rectilinear polarization of the incident solar radiation and the role of producing electricity.

21. The device as claimed in claim 1, further comprising a mechanical system for ensuring the circulation of the gaseous or liquid fluids between and/or around the glazed wall.

22. The device for collecting solar energy as claimed in claim 1, further comprising a solid or flexible frame or support made of metal, wood or composite materials that is capable of adapting the collecting device to windows, sliding bay windows, greenhouse walls, swimming pool covers, garden sheds, aircraft windows, skylights, transport vehicle windows, billboards, shop windows, tiles, roofs, and to all devices that use transparent materials in the fields of construction, transport vehicles, bill posting and broadcasting of images, including electronic display screens.
